(19) United States
(12) Patent Application Publication
(10) Pub. No.: US 2014/0117550 A1
(43) Pub. Date: May 1, 2014

(54) SEMICONDUCTOR DEVICE INCLUDING AN INSULATING LAYER, AND METHOD OF FORMING THE SEMICONDUCTOR DEVICE

(71) Applicants: International Business Machines Corporation, Armonk, NY (US); Renesas Electronics Corporation, Kawasaki-shi (JP)

(72) Inventors: Koichi Motoyama, Kawasaki-shi (JP); Oscar Van Der Straten, Armonk, NY (US)

(73) Assignees: International Business Machines Corporation, Armonk, NY (US); Renesas Electronics Corporation, Kawasaki-shi (JP)

(21) Appl. No.: 14/066,360

(22) Filed: Oct. 29, 2013

Related U.S. Application Data
(60) Provisional application No. 61/719,571, filed on Oct. 29, 2012.

(51) Int. Cl. H01L 21/768; H01L 23/48

(52) U.S. Cl. CPC H01L 21/76843; H01L 23/48; H01L 21/7684; H01L 21/76882
USPC 257/751; 438/653

(57) ABSTRACT

A method of forming a semiconductor device, includes depositing first copper material by physical vapor deposition (PVD) on an insulating layer and on a barrier material formed on a sidewall and a bottom of a trench in the insulating layer, heating the first copper material to reflow the first copper material into the trench, depositing a second copper material by PVD on the insulating layer, on the barrier material and on the first copper material, and heating the second copper material to reflow the second copper material into the trench such that the second copper material is formed on the first copper material and on the sidewall of the trench, the first and second copper materials forming a copper layer in the trench, an amount of sulfur and chlorine in the copper layer being less than 1ppm.

### CROSS REFERENCE TO RELATED APPLICATIONS

This Application claims priority to U.S. Provisional Patent Application No. 61/719,571 which was filed on Oct. 29, 2012, and is incorporated by reference herein.

### BACKGROUND OF THE INVENTION

1. Field of the Invention

The present invention relates generally to a semiconductor device and, more particularly, to a semiconductor device including an insulating layer, and a method of forming the semiconductor device.

2. Description of the Related Art

In conventional methods, a barrier material is formed in a trench (e.g., trench, via, narrow line, etc.) in an insulating layer of a semiconductor device, and a copper material (e.g., pure copper or copper alloys) is formed on the barrier material in the trench by electrochemical plating. The copper material is then planarized by chemical-mechanical polishing (CMP).

However, in such conventional methods, nodular defects are formed at an interface between the copper material and barrier material (e.g., a metal such as tantalum) after CMP. Nodular defects are corrosion products formed by an electrochemical reaction at the interface between barrier and copper material after CMP. The nodular defects may degrade line-to-line leakage performance, especially for narrow spacing (e.g., 32 nm or less) between narrow lines (e.g., 32 nm or less).

Conventionally, there are three methods of solving the problem of nodular defect formation after CMP. First, the manufacturer of the semiconductor device may minimize the time (e.g., q-time, or time between processes) between the CMP, and the subsequent dielectric cap deposition. This is one of the best conventional ways to avoid nodular defect formation. Second, the manufacturer may apply post-plating anneal with high temperature. This is also effective to suppress nodular defect formation. Third, the manufacturer may to apply a post-CMP chemical treatment.

However, there are drawbacks to the three conventional methods of solving the problem of nodular defect formation. In particular, with respect to the first method, for mass production, a process which needs q-time control is not preferable because it may affect lot movement significantly. With respect to the second method, a high temperature anneal may cause via-chain yield degradation. With respect to the third method, applying a post-CMP chemical treatment raises process costs and increases process steps.

### SUMMARY

In view of the foregoing and other exemplary problems, disadvantages, and drawbacks of the aforementioned conventional methods, an exemplary aspect of the present invention is directed to method, device and system which may reduce a formation of nodular defects and, therefore, have a reduced line-to-line leakage current over conventional methods.

An exemplary aspect of the present invention is directed to a method of forming a semiconductor device. The method includes depositing first copper material by physical vapor deposition (PVD) on an insulating layer and on a barrier material formed on a sidewall and a bottom of a trench in the insulating layer, heating the first copper material to reflow the first copper material into the trench, depositing a second copper material by PVD on the insulating layer, on the barrier material and on the first copper material, and heating the second copper material to reflow the second copper material into the trench such that the second copper material is formed on the first copper material and on the sidewall of the trench, the first and second copper materials forming a copper layer in the trench, an amount of sulfur and chlorine in the copper layer being less than 1 ppm.

Another exemplary aspect of the present invention is directed to a method of forming a semiconductor device. The method includes depositing a copper material by physical vapor deposition (PVD) on an insulating layer including a trench, and on a barrier material formed on a sidewall and a bottom of the trench, and during the depositing of the copper material, heating the copper material and applying an AC bias to the substrate to reflow the copper material into the trench, the copper material forming a copper layer in the trench, an amount of sulfur and chlorine in the copper layer being less than 1 ppm.

Another exemplary aspect of the present invention is directed to a semiconductor device which includes an insulating layer including a trench formed in a surface of the insulating layer, a barrier layer formed on a sidewall and a bottom of the trench, and a copper layer formed in the trench on the barrier layer and including an upper surface which is coplanar with the surface of the insulating layer, an amount of sulfur and chlorine in the copper layer being less than 1 ppm.

With its unique and novel features, the present invention may provide a method of forming a semiconductor device which may reduce a formation of nodular defects and, therefore, have a reduced line-to-line leakage current over conventional methods.

### BRIEF DESCRIPTION OF THE DRAWINGS

The foregoing and other exemplary purposes, aspects and advantages will be better understood from the following detailed description of the embodiments of the invention with reference to the drawings, in which:

FIG. 1 illustrates a method 100 of forming a semiconductor device, according to an exemplary aspect of the present invention;

FIG. 2 illustrates a method 200 of forming a semiconductor device, according to an exemplary aspect of the claimed invention;

FIGS. 3A-3H illustrate a method 300 of forming a semiconductor, according to an exemplary aspect of the present invention;

FIG. 3I illustrates an upper surface (S_{Cu4}) of the fourth copper material 230d which is planarized (e.g., by using chemical mechanical polishing (CMP) with the upper surface (Sᵢₙₛ) of the insulating layer 210, according to an exemplary aspect of the present invention;

FIG. 4 illustrates a system 400 for forming a semiconductor device, according to an exemplary aspect of the present invention;

FIG. 5 illustrates a method 500 of forming a semiconductor device, according to another exemplary aspect of the present invention;

FIG. 6 illustrates an exemplary manner of implementing the method 500, according to an exemplary aspect of the present invention;

FIG. 7A illustrates a schematic diagram of a pair of post-CMP lines 700 (e.g., narrow lines having a width which is less than 40nm) filled by electrochemical plating, according to a conventional method;

FIG. 7B illustrates a schematic diagram of a pair of post-CMP lines 750 (e.g., narrow lines having a width which is less than 40nm) filled according to an exemplary aspect of the present invention (e.g., method 100, 500, system 400, etc.);

FIG. 8A illustrates a top-down scanning electron microscope (SEM) image of post-CMP copper lines 800 formed in a trench by conventional electrochemical plating;

FIG. 8B illustrates a top-down SEM image of post-CMP copper lines 850 formed in a trench by the exemplary aspects of the present invention (e.g., a PVD reflow process);

FIG. 9 illustrates a graph which plots test data from experiments conducted by the inventors;

FIG. 10 illustrates a typical hardware configuration 1000 that may be used to implement the system and method of the present invention, in accordance with an exemplary aspect of the present invention; and

FIG. 11 illustrates a magnetic data storage diskette 1100 and compact disc (CD) 1102 that may be used to store instructions for performing the inventive method of the present invention, in accordance with an exemplary aspect of the present invention.

### DETAILED DESCRIPTION OF THE EXEMPLARY EMBODIMENTS OF THE INVENTION

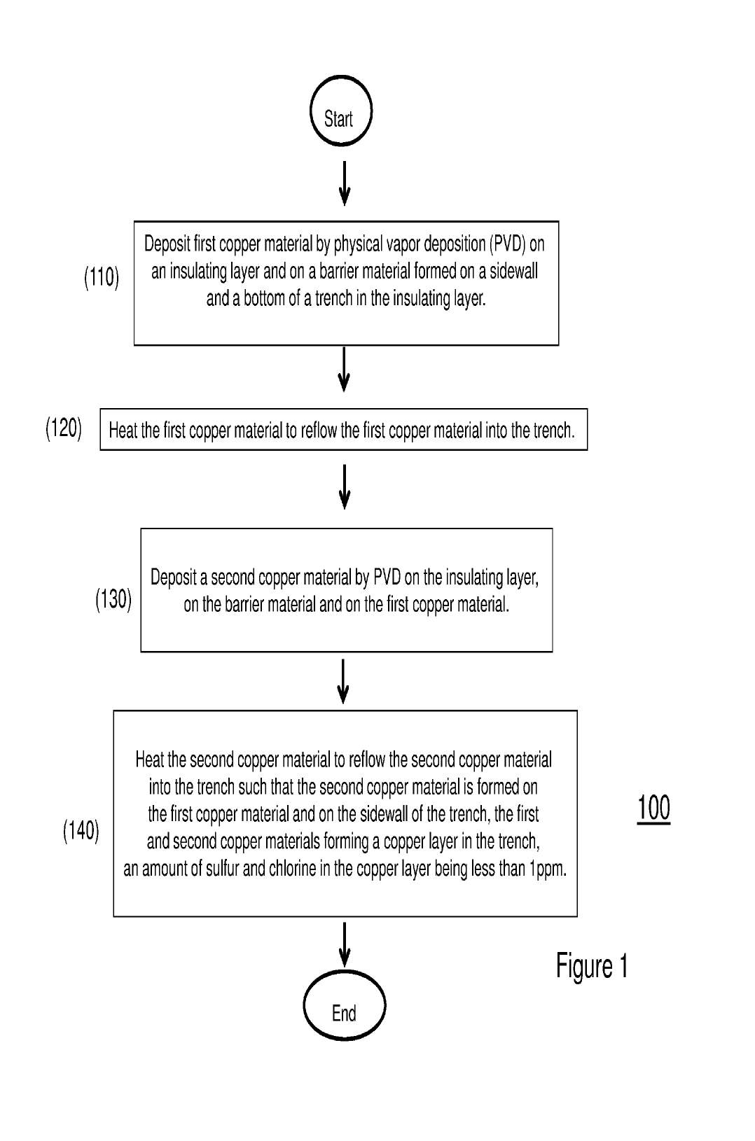

Referring now to the drawings, FIGS. 1-6, 7B, 8B and 9-11 illustrate some of the exemplary aspects of the present invention.

The exemplary aspects of the present invention may solve the problem of nodular defect formation after CMP without the drawbacks of the conventional methods. In particular, the exemplary aspects of the present invention may not require strict q-time control (so lot movement is not adversely affected), may not require a high temperature anneal (so via-chain yield degradation is avoided), and may not require post-CMP chemical treatment (so an increase in process costs and process steps are avoided).

As noted above, in conventional methods, copper is formed in a trench by electrochemical plating. The electrochemical plating uses a plating electrolyte which includes sulfur and chlorine, which appear as impurities (e.g., more than 10 ppm, respectively) in the copper.

Based on their experimentation, the inventors have concluded that nodular defects are formed at the interface between copper and barrier material (e.g., tantalum) by an electrochemical reaction (e.g., corrosion) after the CMP, and since sulfur and chlorine enhance the corrosive reaction of copper, if sulfur and chlorine are incorporated in copper line, then nodular defects can form more easily at the interface. Therefore, the inventors concluded that nodular defect formation at the interface of the copper and barrier material may be suppressed by reducing an amount of sulfur and chlorine in the copper.

FIG. 1 illustrates a method 100 of forming a semiconductor device, according to an exemplary aspect of the present invention.

As illustrated in FIG. 1, the method 100 includes depositing (110) first copper material by physical vapor deposition (PVD) on an insulating layer and on a barrier material formed on a sidewall and a bottom of a trench in the insulating layer, heating (120) the first copper material to reflow the first copper material into the trench, depositing (130) a second copper material by PVD on the insulating layer, on the barrier material and on the first copper material, and heating (140) the second copper material to reflow the second copper material into the trench such that the second copper material is formed on the first copper material and on the sidewall of the trench, the first and second copper materials forming a copper layer in the trench, an amount of sulfur and chlorine in the copper layer being less than 1ppm.

The method 100 may also include performing chemical mechanical polishing (CMP) to planarize an upper surface of the copper layer and an upper surface of the insulating layer.

Further, after the heating of the second copper material an elevation of an upper surface of the second copper material may be less than an elevation of the upper surface of the insulating layer (e.g., the trench being formed in the upper surface of the insulating layer). Thus, the method 100 may also include repeating the depositing of the second copper material and the heating of the second copper material until an elevation of an upper surface of the second copper material (after the heating of the second copper material) is greater than an elevation of the upper surface of the insulating layer.

Further, the method 100 may also include selecting an optimum deposition rate for depositing the first copper material and the second copper material, the repeating of the depositing of the second copper material and the heating of the second copper material being performed a number of times which is based on the selected optimum deposition rate. Alternatively, the method 100 may include selecting an optimum number of times for performing the repeating of the depositing of the second copper material and the heating of the second copper material, the deposition rate for depositing of the first copper material and the second copper material, being based on the selected optimum number of times.

After the CMP, an interface between the copper layer (e.g., embedded copper layer) and the barrier material (e.g., an inner sidewall of the barrier layer formed on a sidewall of the trench) may be substantially devoid of a nodular defect formation. That is, the sidewall of the copper layer may be uniform (e.g., flat) at the interface. Therefore, a line-to-line leakage current may be reduced as compared to a conventional device having a sidewall which includes a nodular defect formation.

Thus, in an exemplary aspect of the present invention, a trench may be filled with a copper material (e.g., pure copper, copper alloy, etc.) by using PVD (e.g., only PVD), and without necessarily using electrochemical plating. That is, an entire volume of the trench which is bounded by the sidewalls of the barrier material (e.g., the inner sidewalls of the barrier layer which is formed on the sidewalls of the trench) and the bottom surface of the barrier material (e.g., the inner surface of the barrier layer which is formed on the bottom of the trench) may be filled with a copper material which is formed by PVD.

In the PVD, a thin film of copper material (e.g., pure copper, copper alloy, etc.) is deposited on the insulating layer. Generally, the PVD may be performed in a deposition chamber, where the copper material to be deposited is converted into vapor by physical means, the vapor is transported across a region of low pressure from its source (e.g., a copper rod, bar, sheet, etc.) to the insulating layer (e.g., the barrier material in the trenches of the insulating layer), and the vapor undergoes condensation on the insulating layer to form the thin film of copper material.

In particular, the PVD may include sputtering of the copper material in which atoms are dislodged from the surface of a material as a result of collision with high-energy particles. In particular, in the deposition chamber, ions (e.g., ions of an inert gas such as argon) are generated and directed at a target (e.g., a copper rod, bar, sheet, etc.), the ions sputter atoms or molecules of the copper material from the target, the sputtered atoms or molecules get transported to a surface of the insulating layer (e.g., the barrier material in the trenches of the insulating layer) through a region of reduced pressure, and the sputtered atoms condense on the insulating layer, forming a thin film.

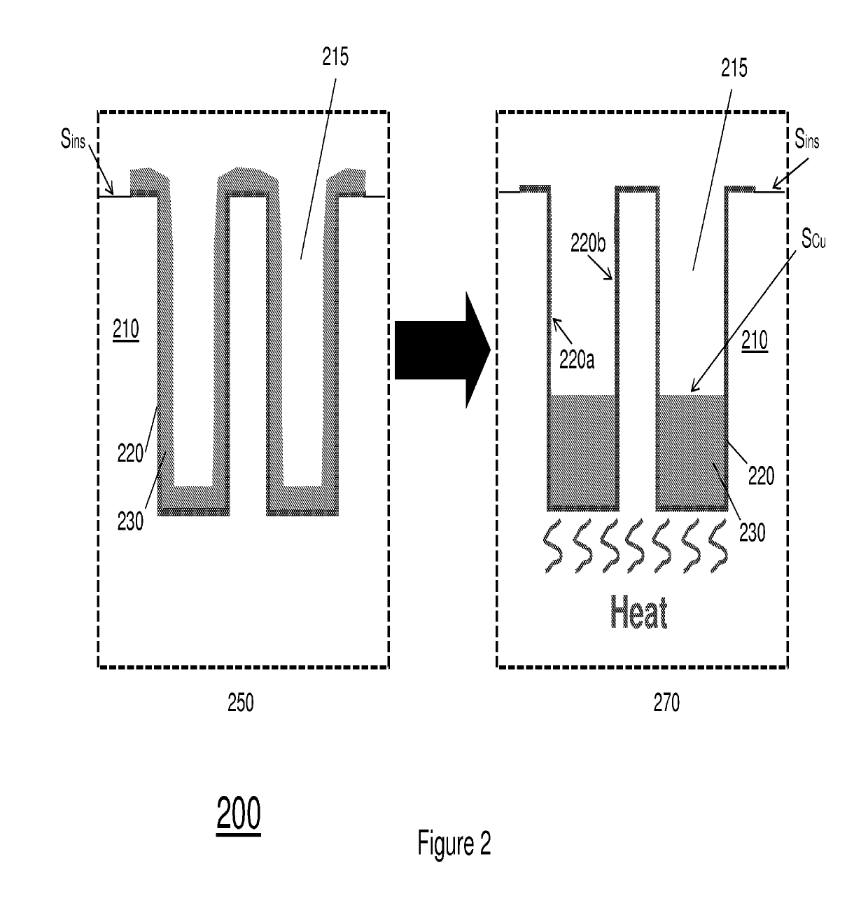

FIG. 2 illustrates a method 200 of forming a semiconductor device, according to an exemplary aspect of the claimed invention. As illustrate in FIG. 2, the method 200 may include a PVD copper thermal reflow process.

The method 200 illustrated in FIG. 2 may correspond, for example, to the depositing (110) of the first copper material, and the heating (120) of the first copper material, in the method 100. By using the method 200, a plurality of trenches (e.g., small features) may be filled completely with PVD copper material.

In the method 200, a substrate (e.g., a semiconductor wafer) having an insulating layer 210 (e.g., a patterned structure) formed thereon (a trench 215 being formed in the insulating layer 210 and a barrier material 220 (e.g., Ta, TaN, TaN/Ta, Ti, TiN/Ti, TaN/Ru, TaN/Ta/Ru, TaN/Co, and TaN/Ta/Co) being formed on a bottom and a sidewall of the trench 215), is placed in a deposition chamber 250. As illustrated in FIG. 2, a copper material 230 is deposited by physical vapor deposition (PVD) (e.g., conformally formed) on the insulating layer 210 and on the barrier material 220, while the substrate is in the deposition chamber.

For example, the trenches 215 in FIG. 2 may include a pair of lines (e.g., elongated trenches which form narrow lines) having a width in a range of 10 nm to 40 nm, and which may be separated by a distance of 50 nm or less.

It should be noted that a thickness of the copper material 230 which is deposited by PVD (e.g., sputtering) may be substantially uniform across the surface of the insulating layer 210 (e.g., across an entire surface of the insulating layer 210). That is, a thickness of the copper material 230 deposited on the sidewalls 220a, 220b and the bottom of the barrier material 220 in the trench 215, is the substantially equal to a thickness of the copper material 230 deposited on the upper surface (Sᵢₙₛ) of the insulating layer 210.

For purposes of the exemplary aspect of the present invention, the copper material 230 may have a thickness in a range of 10 nm to 50 nm, or more particularly, in a range from 15 nm to 25 nm. The thickness of the copper material 230 to be deposited may depend on several factors such as the width and depth of the trenches in the insulating layer, the aspect ratio of the trenches, the overall surface area of the insulating layer, and the number of cycles (e.g., deposition-reflow cycles) to be used to fill the trenches (e.g., the more cycles that are to be used, the less thickness to be deposited).

After the depositing of the copper material 230, the substrate may be transferred (indicated by the arrow in FIG. 2) out of the deposition chamber 250 and into a gas chamber 270. As illustrated in FIG. 2, the copper material 230 is heated to reflow the copper material 230 into the trench 215, while the substrate is in the gas chamber 270.

That is, in the second step, the heating of the substrate (e.g., heating of the copper material) may cause the copper material 230 on an upper surface (Sᵢₙₛ) of the insulating layer 210 to flow along the upper surface (Sᵢₙₛ) in a horizontal direction and into the trench 215 so that there is substantially no copper material 230 remaining on the upper surface (Sᵢₙₛ). Further, after the heating of the substrate, the copper material 230 in the trench 215 has a substantially horizontal and uniform upper surface (S_{Cu}) which extends from a sidewall 220a of the barrier material 220 to the other sidewall 220b of the barrier material 220 (e.g., a sidewall of the barrier material 220 which is opposite the sidewall 220a). That is, there is substantially no copper material 230 remaining on the sidewalls 220a, 220b of the barrier material 220 above the upper surface (S_{Cu}) of the copper material 230.

It should be noted that although FIG. 2 illustrates the first and second steps being performed in separate chambers 250, 270, it is possible for the first and second steps to be performed in one chamber which may be used for both deposition of the copper material 230, and for heating (e.g., reflow) of the copper material 230.

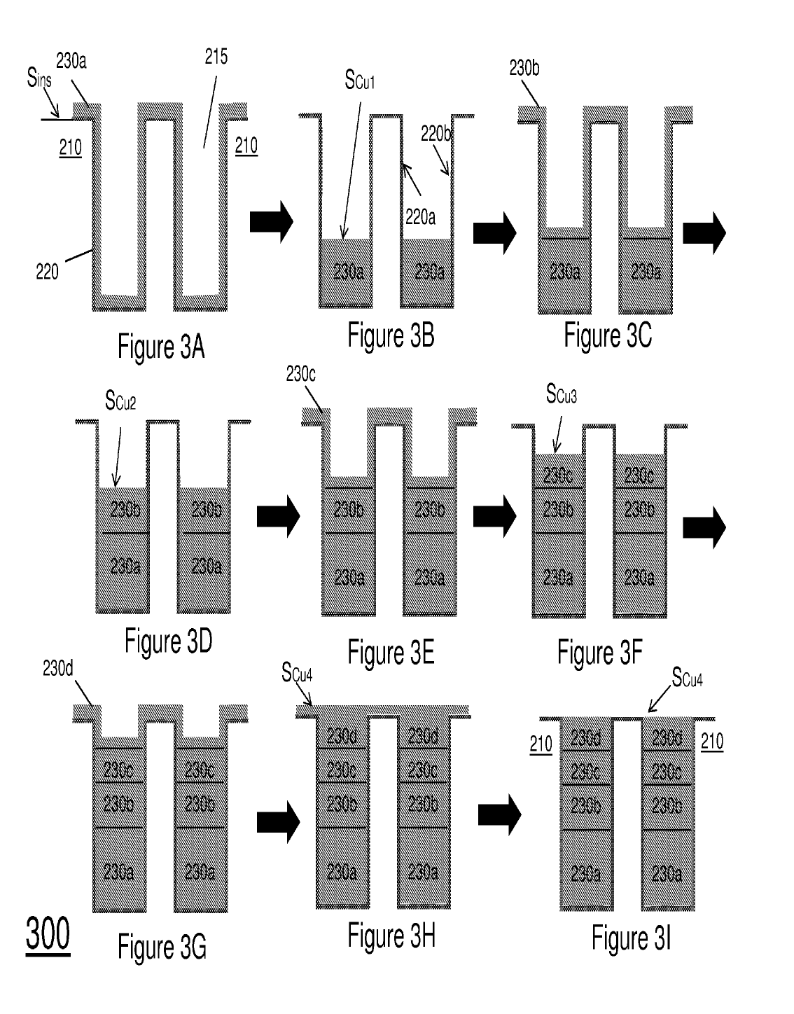

FIGS. 3A-3H illustrate a method 300 of forming a semiconductor, according to an exemplary aspect of the present invention. As illustrated in FIGS. 3A-3H, the method 300 may include a process sequence of trench filling with PVD copper by multi-cycle thermal reflow.

In particular, FIGS. 3A-3B illustrate a first cycle in a multi-cycle process. In FIG. 3A, a first copper material 230a is deposited by physical vapor deposition (PVD) on the insulating layer 210 (e.g., on the upper surface (Sᵢₙₛ) of the insulating layer 210) and on the barrier material 220 (e.g., a sidewall of the barrier layer formed on the sidewall of the trench 215). In FIG. 3B, the first copper material 230a is heated to reflow the first copper material 230a into the trench 215.

As illustrated in FIG. 3B, the heating of the substrate causes the first copper material 230a on the upper surface (Sᵢₙₛ) of the insulating layer 210 to flow along the upper surface (Sᵢₙₛ) in a horizontal direction and into the trench 215 so that there is substantially no first copper material 230a remaining on the upper surface (Sᵢₙₛ). Further, at the completion of the first cycle (e.g., at completion of the reflow), the first copper material 230a in the trench 215 has a substantially horizontal and uniform upper surface (S_{Cu1}) which extends from a sidewall 220a of the barrier material 220 to the other sidewall 220b of the barrier material 220. That is, there is substantially no first copper material 230a remaining on the sidewalls 220a, 220b of the trench 220 above the upper surface (S_{Cu1}) of the copper material 230a.

Further, as illustrated in FIG. 3B, after reflow, the upper surface S_{Cu1} of the first copper material 230a is formed below the upper surface Sᵢₙₛ of the insulating layer 210. That is, only a portion of a volume of the trench 215 is filled by the first copper material 230a. In particular, an amount of the volume of the trench 215 filled by the first copper material 230a may range from 5% to 70% of the total volume of the trench 215.

FIGS. 3C-3D illustrate a second cycle in the multi-cycle process. In FIG. 3C, a second copper material 230b is deposited by physical vapor deposition (PVD) on the insulating layer 210, on the first copper material 230a, and on the barrier material 220 (e.g., a sidewall of the barrier layer formed on the sidewall of the trench 215). In FIG. 3D, the second copper material 230b is heated to reflow the second copper material 230b into the trench 215.

As illustrated in FIG. 3D, the heating of the substrate causes the second copper material 230b on the upper surface (Sᵢₙₛ) of the insulating layer 210 to flow along the upper surface (Sᵢₙₛ) in a horizontal direction and into the trench 215 so that there is substantially no second copper material 230b remaining on the upper surface (Sᵢₙₛ). Further, at the completion of the second cycle (e.g., at completion of the reflow), the second copper material 230b in the trench 215 has a substantially horizontal and uniform upper surface (S_{Cu2}) which extends from a sidewall 220a of the barrier material 220 to the other sidewall 220b of the barrier material 220. That is, there is substantially no second copper material 230b remaining on the sidewalls 220a, 220b of the trench 220 above the upper surface (S_{Cu2}) of the second copper material 230b.

Further, as illustrated in FIG. 3D, after reflow, the upper surface S_{Cu2} of the second copper material 230b is formed below the upper surface Sᵢₙₛ of the insulating layer 210. That is, only a portion of a volume of the trench 215 is filled by the second copper material 230b. In particular, a volume of the trench 215 filled by the second copper material 230b may range from 5% to 50% of the total volume of the trench 215.

Further, as illustrated in FIG. 3D, the volume of the trench 215 which is filled by the second copper material 230b may be less than the volume of the trench 215 which is filled by the first copper material 230a. However, in another aspect of the present invention, the volume of the trench 215 which is filled by the second copper material 230b may be equal to or greater than the volume of the trench 215 which is filled by the first copper material 230a.

FIGS. 3E-3F illustrate a third cycle in the multi-cycle process. In FIG. 3E, a third copper material 230c is deposited by physical vapor deposition (PVD) on the insulating layer 210, on the first and second copper materials 230a, 230b, and on the barrier material 220 (e.g., a sidewall of the barrier layer formed on the sidewall of the trench 215). In FIG. 3F, the third copper material 230c is heated to reflow the third copper material 230c into the trench 215.

As illustrated in FIG. 3F, the heating of the substrate causes the third copper material 230c on the upper surface (Sᵢₙₛ) of the insulating layer 210 to flow along the upper surface (Sᵢₙₛ) in a horizontal direction and into the trench 215 so that there is substantially no third copper material 230c remaining on the upper surface (Sᵢₙₛ). Further, at the completion of the third cycle (e.g., at completion of the reflow), the third copper material 230c in the trench 215 has a substantially horizontal and uniform upper surface (S_{Cu3}) which extends from a sidewall 220a of the barrier material 220 to the other sidewall 220b of the barrier material 220. That is, there is substantially no third copper material 230c remaining on the sidewalls 220a, 220b of the trench 220 above the upper surface (S_{Cu3}) of the third copper material 230b.

Further, as illustrated in FIG. 3F, after reflow, the upper surface S_{Cu3} of the third copper material 230c is formed below the upper surface Sᵢₙₛ of the insulating layer 210. That is, only a portion of a volume of the trench 215 is filled by the third copper material 230c. In particular, an amount of the volume of the trench 215 filled by the third copper material 230c may range from 5% to 50% of the total volume of the trench 215.

Further, as illustrated in FIG. 3F, the volume of the trench 215 which is filled by the third copper material 230c may be less than the volume of the trench 215 which is filled by the first copper material 230a and/or the volume of the trench 215 which is filled by the by the second copper material 230b. However, in another aspect of the present invention, the volume of the trench 215 which is filled by the third copper material 230c may be equal to or greater than the volume of the trench 215 which is filled by the first copper material 230a and/or the volume of the trench 215 which is filled by the by the second copper material 230b.

FIGS. 3G-3H illustrate a fourth cycle in the multi-cycle process. In FIG. 3E, a fourth copper material 230c is deposited by physical vapor deposition (PVD) on the insulating layer 210, on the first, second and third copper materials 230a, 230b, 230c and on the barrier material 220 (e.g., a sidewall of the barrier layer formed on the sidewall of the trench 215). In FIG. 3H, the fourth copper material 230d is heated to reflow the fourth copper material 230d into the trench 215.

As illustrated in FIG. 3H, the heating of the substrate causes the fourth copper material 230d on the upper surface (Sᵢₙₛ) of the insulating layer 210 to flow along the upper surface (Sᵢₙₛ) in a horizontal direction and into the trench 215. However, unlike after the first, second and third cycles, after the fourth cycle there is some of the fourth copper material 230d remaining on the upper surface (Sᵢₙₛ).

That is, as illustrated in FIG. 3H, after reflow, the volume of the trench within the barrier material 220 is filled with a plurality of copper layers including a first layer formed by the first copper material 230a, a second layer formed by the second copper material 230b, a third layer formed by the third copper material 230c, and a fourth layer formed by the fourth copper material 230d. Further, the upper surface S_{Cu4} of the fourth copper material 230d is formed below the upper surface Sᵢ, of the insulating layer 210. The thickness of the fourth copper material 230d remaining on the upper surface (Sᵢₙₛ) should be in a range from 1 nm to 20 nm, in order to ensure that the trench 215 is sufficiently filled by the first, second, third and fourth copper materials 230a, 230b, 230c, 230d.

Further, the volume of the trench 215 which is filled by the fourth copper material 230d may be less than, equal to, or greater than the volume of the trench 215 which is filled by the first copper material 230a and/or the volume of the trench 215 which is filled by the by the second copper material 230b, and/or the volume of the trench 215 which is filled by the by the third copper material 230c.

It should be noted that although FIGS. 3A-3H illustrate a multi-cycle process which includes four cycles (i.e., four deposition-reflow cycles), any number of cycles may be used. In the interest of time, the minimum number of cycles may be used. To fill the gap with fewer cycles would require that an increase in the thickness of the deposited copper material. However, if the thickness of the deposited copper material is too great, then a “pinching off” of the copper material may occur, in which the deposited copper material on the sidewalls 220a, 220b are joined together which may result in a void forming in the copper material. Thus, the minimum number of cycles may be determined by the maximum thickness of the deposited copper material, which may be determined by the risk of “pinch off”.

As illustrated in FIG. 3I, upon completion of the fourth cycle, the upper surface (S_{Cu4}) of the fourth copper material 230d may be planarized (e.g., by using chemical mechanical polishing (CMP)) with the upper surface (Sᵢₙₛ) of the insulating layer 210.

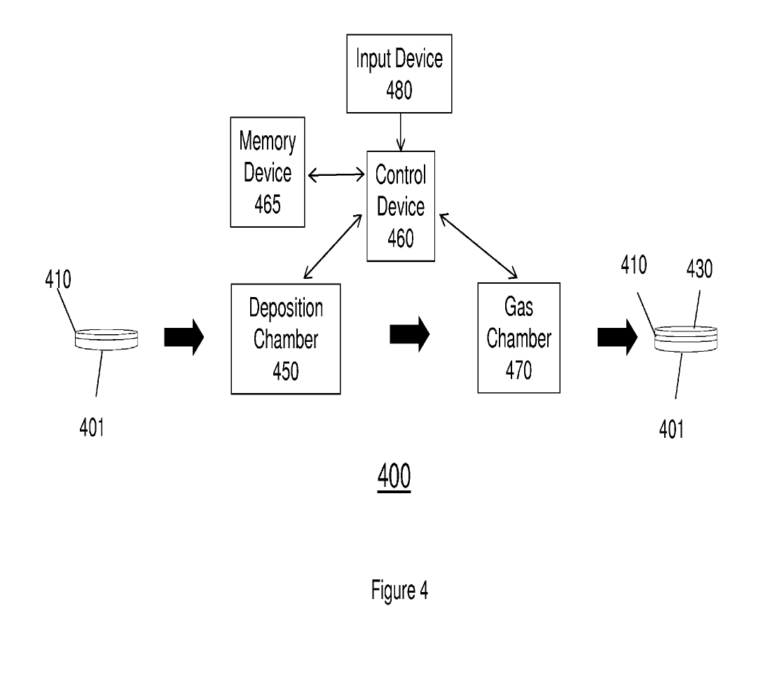

FIG. 4 illustrates a system 400 for forming a semiconductor device, according to an exemplary aspect of the present invention.

As illustrated in FIG. 4, the system 400 includes a deposition chamber 450 in which a deposition of a copper material is performed on a semiconductor wafer 401, and a control device 460 (e.g., controller, microprocessor, etc.) which controls an operation of the deposition chamber 450. The system 400 also includes a gas chamber 470 which in which a reflow of the copper material is performed on the semiconductor wafer 401, to produce a plurality of layers of copper material in a trench of an insulating layer 410 on the semiconductor wafer 401, the uppermost layer of copper material 430 (e.g., fourth copper material 230d in FIG. 3H) of the plurality of layers being formed on an upper surface (e.g., Sᵢₙₛ in FIG. 3A) of the insulating layer 410.

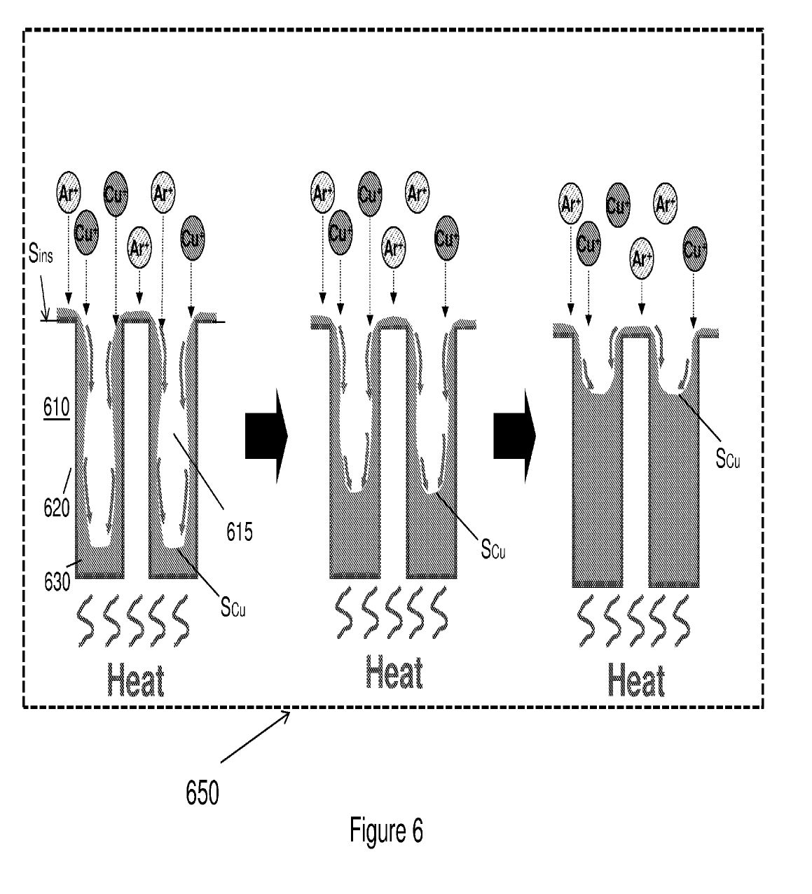

The control device 460 may also control an operation of the gas chamber 470. Alternatively, there could be another control device which separately controls an operation of the gas chamber 470. In addition, the system 400 may include one processing chamber which performs both the deposition of the copper material and the reflow of the copper material (e.g., see FIG. 6).

As illustrated in FIG. 4, the deposition chamber 460 and gas chamber 470 may also generate data which the control device 460 may use to control an operation of the chambers 460, 470. For example, the deposition chamber 460 may include a sensor for detecting a weight of the wafer 401 in the chamber 460, so that the deposition chamber 460 may generate weight data which is fed back to the control device 460. In this case, the control device 460 may control an operation of an ion generator in the deposition chamber 460 based on the weight data generated by the gas chamber.

Similarly, the gas chamber 470 may include a sensor for detecting a temperature of the wafer 401 in the chamber 470, so that the gas chamber 470 may generate temperature data which is fed back to the control device 460. In this case, the control device 460 may control an operation of a heater in the gas chamber 470 based on the temperature data generated by the gas chamber 470.

The system 400 may also include a memory device 465 (e.g., random access memory (RAM), read-only memory (ROM), etc.) for storing programs and data. For example, the memory device 465 may store data input by the user, and data generated by the deposition chamber 450 and the gas chamber 470. The memory device 465 may be accessed by the control device 460, and may store data and programs for allowing the control device 460 to control the features and functions of the system 400.

Further, the programs which stored in the memory device 465 and used by the control device 460 to control the features of the system 400, may be updated by the data fed back to the control device 460 from the deposition chamber 450 and the gas chamber 470. For example, if the memory device 465 stores a program which calculates an optimum temperature for performing a reflow of the copper material, and a user manually sets a reflow temperature to be less than the calculated optimum temperature, then control device 460 may adjust the program based on the temperature feedback data, so that in a subsequent operation of the system 400, the optimum temperature calculated by the program may be reduced to reflect the user preference.

The system 400 may also include an input device 480 (e.g., keyboard, mouse, touchscreen, etc.) for inputting control parameters to the control device 460. In particular, the input device 480 and the control device 460 may be integrally formed as a single unit.

For example, a user may use the input device 480 to input the number of deposition-reflow cycles to be performed by the system 400, the desired thickness of the copper material to be deposited, a duration of the deposition of the copper material, a temperature of the wafer during the reflow of copper material, a duration of the reflow of the copper material, etc.

The control device 460 may also be programmed to set some control parameters based on a user input. For example, the control device 460 may include a control panel which displays a graphic user interface (GUI) which a user may manipulate by using the input device 480. The user may view the GUI while inputting data which is used by the control device 460 to set some of the control parameters.

For example, a user may input a trench profile such as a width of a trench, a depth of a trench and whether there is any taper to the trench (e.g., if the trench is tapered to be more narrow at the top than at the bottom, then a thickness of the deposited copper material may be less than if there was no taper), a degree of taper to the trench, a desired thickness of the copper material to be deposited, a duration of the deposition, a number of cycles to be performed, a line spacing between the trenches, a surface area of the insulating layer, a type of copper material being used (e.g., pure copper, copper alloy, etc.), a temperature of the wafer during the reflow, duration of the reflow, and a flow rate of an inert gas during the deposition and during the reflow. This list is merely exemplary and is not exhaustive, and should not be considered as limiting the present invention in any manner.

Based on the data input by the user using the input device 480, the control device 460 may execute a program stored in the memory device 465 to generate a preferred set of operating parameters, which may be displayed on the GUI and viewed by the user. For example, the control device 460 may set (e.g., automatically set) a duration of copper material deposition and/or a duration of the reflow based on trench profile data (e.g., width of the trench, depth of the trench, taper of the trench) input by the user. The control device 460 may also set a number of deposition-reflow cycles based on such trench profile data and/or the type of copper material being used.

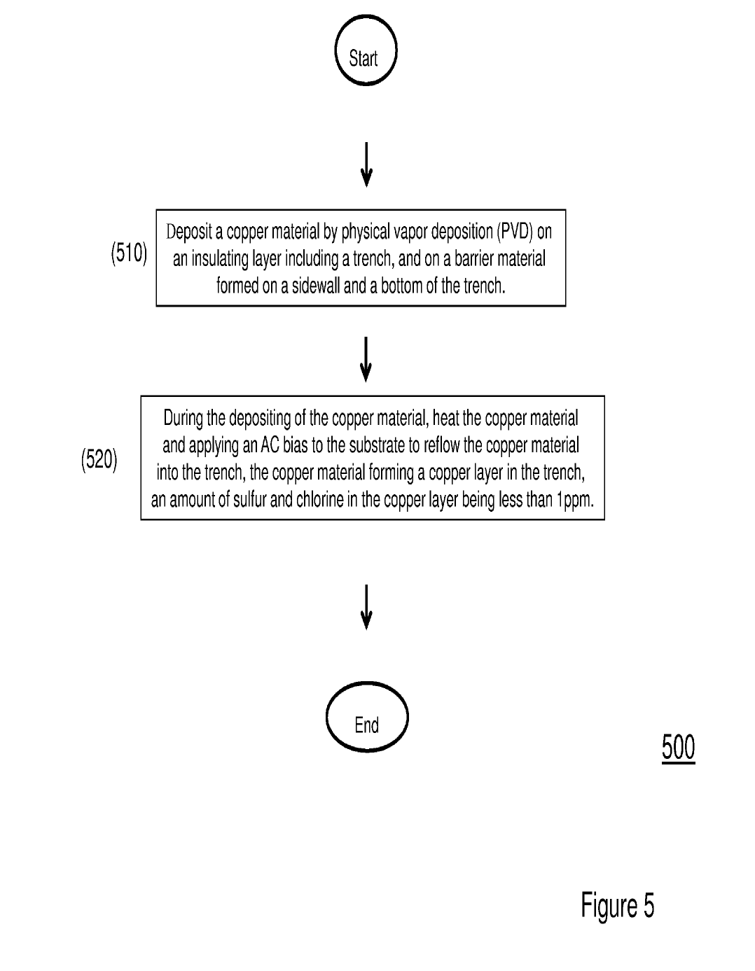

FIG. 5 illustrates a method 500 of forming a semiconductor device, according to another exemplary aspect of the present invention. As illustrated in FIG. 5, the method 500 includes depositing (510) a copper material by physical vapor deposition (PVD) on an insulating layer including a trench (e.g., a trench formed in an upper surface of the insulating layer), and on a barrier material formed on a sidewall and a bottom of the trench, and during the depositing of the copper material, heating (520) the copper material and applying an AC bias to the substrate to reflow the copper material into the trench, the copper material forming a copper layer in the trench, an amount of sulfur and chlorine in the copper layer being less than 1ppm.

Further, the depositing of the copper material and the heating of the copper material may be performed until an elevation of an upper surface of the copper material is greater than an elevation of the upper surface of the insulating layer.

The method 500 may also include selecting an optimum deposition rate for the depositing the copper material. In this case, the depositing of the copper material and the heating of the copper material may be performed for a duration which is based on the selected optimum deposition rate.

The method 500 may also include selecting an optimum duration for performing the depositing of the copper material and the heating of the copper material. In this case, a deposition rate for the depositing of the copper material may be based on the selected optimum duration.

FIG. 6 illustrates an exemplary manner of implementing the method 500. As illustrated in FIG. 6, the method 500 may include a process sequence of trench filling with PVD copper by thermal and ion assisted reflow.

As illustrated in FIG. 6, in the method 500, a substrate (e.g., a semiconductor wafer) having an insulating layer 610 formed thereon (a trench 615 being formed in the insulating layer 610 and a barrier material 620(e.g., Ta, TaN, TaN/Ta, Ti, TiN/Ti, TaN/Ru, TaN/Ta/Ru, TaN/Co, and TaN/Ta/Co) being formed on a bottom and a sidewall of the trench 615), is placed in a processing chamber 650. The chamber 650 may be a combination of the deposition chamber 250 and the reflow chamber 295 in FIG. 2, and may include all of the features of the chambers 250, 270 (and the chambers 450, 470 in FIG. 4).

As illustrated in FIG. 6, in the chamber 650, a copper material 630 is deposited by physical vapor deposition (PVD) (e.g., conformally formed) on the insulating layer 610 and on the barrier material 620. During the depositing of the copper material, the substrate is heated and a electrical bias (e.g., an AC bias) is applied to the substrate to reflow the copper material into the trench 615. Thus, during the depositing, the electrical bias may cause ions of inert gas (e.g., Argon ions) which are present in the processing chamber 650 to assist the reflow of the copper material into the trench 615.

That is, in the method 500 the copper material may be continuously (i.e., without interruption) deposited on the upper surface (Sᵢₙₛ) of the insulating layer 610 and reflown into the trench 615. As a result, as illustrated in FIG. 6, over time (e.g., time progressing from left to right in FIG. 6, as illustrated by the arrows), the upper surface (S_{Cu}) of the copper material 630 rises in the trench 615. When the upper surface (S_{Cu}) of the copper material 630 rises above the upper surface (_{Sins}) of the insulating layer 610, the heating of the substrate and the electrical bias may be stopped. The thickness of the copper material 630 remaining on the upper surface (Sᵢₙₛ) should be in a range from 1 nm to 20 nm, in order to ensure that the trench 215 is sufficiently filled by the copper material 630.

The upper surface (S_{Cu}) of the copper material 630 may then be planarized (e.g., by CMP) so that the upper surface of the copper material 630 in the trench is coplanar with the upper surface of the insulating layer 610 (e.g., see FIG. 3I).

The method 500 may eliminate the need for transferring the substrate (e.g., semiconductor wafer) including the insulating layer 610 back and forth to and from the deposition chamber 250 and the gas chamber 270. Therefore, the time needed to fill the trench 615 may be less than the time needed to fill the trench 215 in FIGS. 3A-3H.

In addition, the process time of the method 500 can be modulated depending on feature size (e.g., width of the trench, depth of the trench, etc.). For example, a process time for wider and deeper trenches may be greater than a process time for narrower and shallower trenches. Similarly, a deposition rate and/or a reflow rate may be modulated depending on the feature size. For example, a deposition rate and/or a reflow rate for a wider and deeper trench may be greater than a deposition rate and/or a reflow rate for narrow and shallow trenches.

Similarly, the process time of the method 500 can be modulated depending on the number of trenches which are to be filled. For example, a process time for more trenches may be greater than a process time for fewer trenches. Similarly, a deposition rate and/or a reflow rate may be modulated depending on the number of trenches which are to be filled. For example, a deposition rate and/or a reflow rate for more trenches may be greater than a deposition rate and/or a reflow rate for fewer trenches.

An advantage of the method 100 over the method 500 is that in the method 100, different types of copper materials may be used in different cycles. This may be useful where one type of copper material is, for example, less expensive, more conducive to processing by CMP or is better for bonding to the barrier material (e.g., tantalum) than other types of copper material. For example, if a copper alloy is more conducive to processing by CMP, but pure copper provides a better bond with the barrier material, then the copper alloy may be used for the copper material 230d, whereas pure copper may be used for copper materials 230a, 230b and 230c.

It should be noted that the system 400 may also be used to implement the method 500. In this case, the deposition chamber 450 and gas chamber 470 may be replaced by the processing chamber 650 in FIG. 6. The features and functions of the system 400 described above may also be applicable to a system which includes the processing chamber 650.

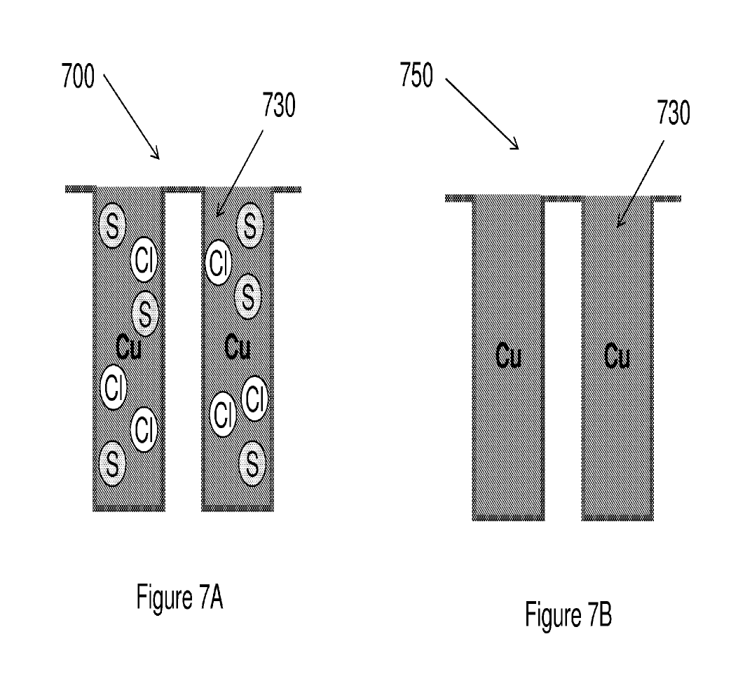

FIG. 7A illustrates a schematic diagram of a pair of post-CMP lines 700 (e.g., narrow lines having a width which is less than 40 nm) filled by electrochemical plating, according to a conventional method. FIG. 7B illustrates a schematic diagram of a pair of post-CMP lines 750 (e.g., narrow lines having a width which is less than 40 nm) filled according to an exemplary aspect of the present invention (e.g., method 100, 500, system 400, etc.). A distance between the lines 700 may be 50 nm or less, and a distance between the lines 750 may be 50 nm or less.

As illustrated in FIG. 7A, the copper material 730 of the lines 700 (e.g., elongated trenches) filled by electrochemical plating include sulfur and chlorine impurities. In particular, the amount of sulfur and chlorine impurities in the copper material 730 in the lines 700 may be 10 ppm or more. As a result, nodular defects will likely form at an interface between the barrier metal and the copper material 730 in the lines 700, resulting in a line-to-line leakage current between the lines 700.

As illustrated in FIG. 7B, the copper material 730 of the lines 750 filled by the method of the exemplary aspects of the present invention is substantially devoid of sulfur and chlorine impurities. In particular, an amount of sulfur and chlorine in the copper material 730 in the lines 750 may be less than 1ppm. As a result, nodular defects will not likely form at an interface between the barrier metal and the copper material 730 in the lines 750, so that a line-to-line leakage current between the lines 700 may be avoided.

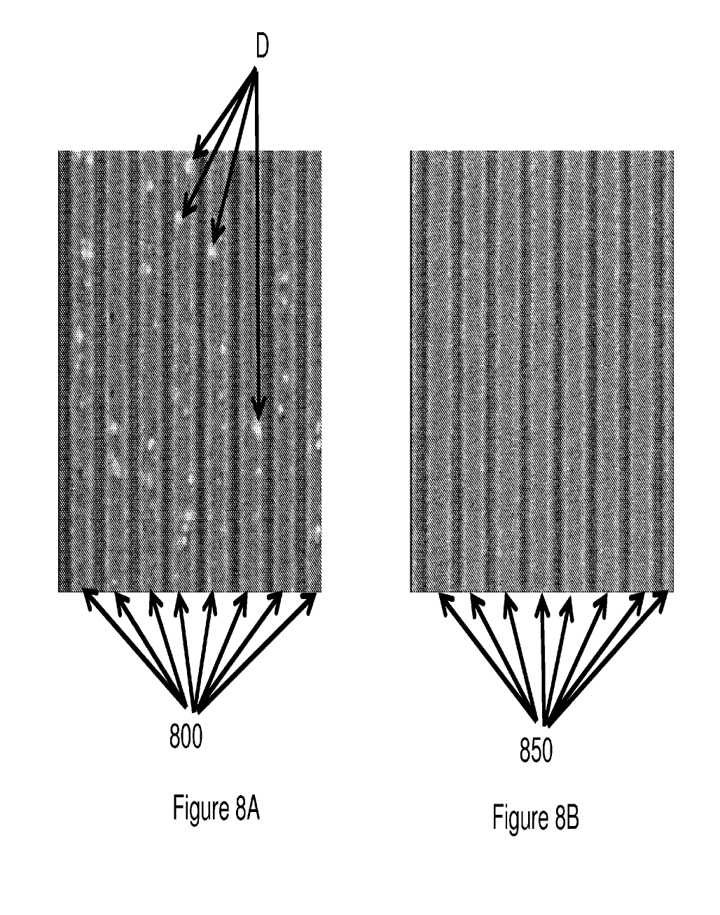

FIG. 8A illustrates a top-down scanning electron microscope (SEM) image of post-CMP copper lines 800 formed in a trench by conventional electrochemical plating , and FIG. 8B illustrates a top-down SEM image of post-CMP copper lines 850 formed in a trench by the exemplary aspects of the present invention (e.g., a PVD reflow process). Both images in FIGS. 8A and 8B were taken 10 days after CMP, to enhance nodular defect growth.

As illustrated in FIG. 8A, a plurality of nodular defects (D) are formed at an interface between the copper material and the barrier material in the copper lines 800 formed by conventional electrochemical plating. As illustrated in FIG. 8B, nodular defects are not formed at an interface between the copper material and the barrier material in the copper lines 850 formed according to the exemplary aspects of the present invention.

The inventors have noted that the leakage current caused by nodular defects resulting from conventional electrochemical plating is especially problematic where the distance between the pair of lines is 50 nm or less. Thus, the post-CMP copper lines 800 would likely suffer from a leakage current between the copper lines 800 especially where the distance between the copper lines 800 is 50 nm or less. However, the post-CMP copper lines 850 would not likely suffer from a leakage current, even where the distance between the copper lines 850 is 50 nm or less.

In particular, the inventors have performed secondary ion mass spectrometer (SIMS) analysis to compare devices formed by electrochemical plating with devices formed according to an exemplary aspect of the present invention (e.g., formed by PVD reflow). Based on the SIMS analysis, in the conventional electrochemical plating method, the sulfur(S) concentration was in a range of 3×10⁴- 4×10⁴ counts per second (C/S), and the chlorine(Cl) concentration was in a range of more than 1×10⁵ (C/S). In contrast, in the PVD reflow method, the sulfur(S) concentration was in a range of less than 3×10³ (C/S), and the chlorine (Cl) concentration was in a range of less than 3×10³ (C/S).

As it is clear from these results, Cu layer formed according to an exemplary aspect of the present invention (e.g., PVD-reflow method) may have a significantly lower concentration of S and Cl than the Cu layer formed by the convention method (e.g., electrochemical plating method). This reduced concentration of S and Cl in the Cu layer formed by PVD may contribute to a reduction of a generation of nodular defects, as compared with the higher concentration of S and Cl in the Cu layer formed by the conventional method which may promote a generation of nodular defects.

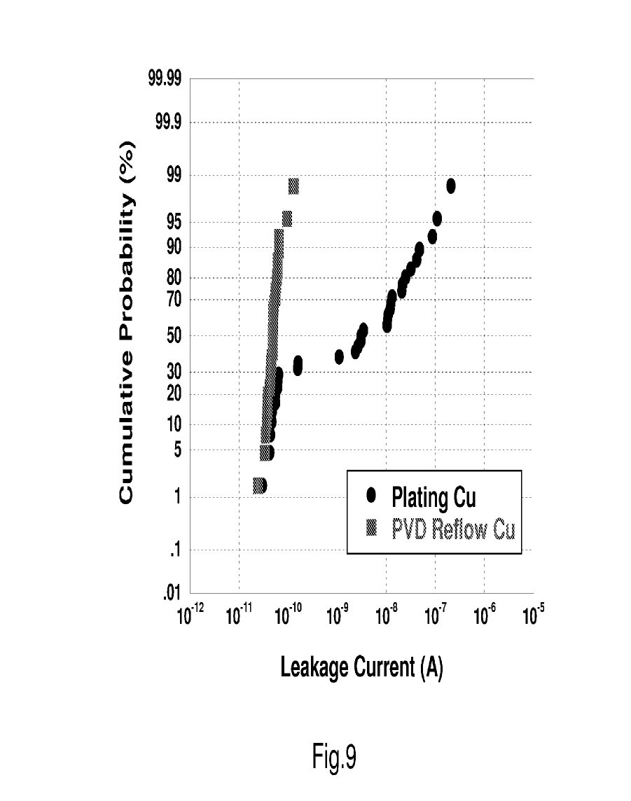

FIG. 9 illustrates a graph which plots test data from experiments conducted by the inventors. In the experiments, the inventors measured a line-to-line leakage current in copper lines filled by conventional electrochemical plating (e.g., copper lines 800 in FIG. 8A) and copper lines filled according to the exemplary aspects of the present invention (e.g., copper lines 850). The graph in FIG. 9 plots the cumulative probability (%) vs. the line-to-line leakage current (A) for both the copper lines filled by conventional electrochemical plating and the copper lines filled according to the exemplary aspects of the present invention.

As illustrated in FIG. 9, the line-to-line leakage current in the copper lines filled by conventional electrochemical plating was in a range from about 10⁻¹¹ A to more than10⁻⁷ A, whereas the line-to-line leakage current in the copper lines filled according to the exemplary aspects of the present invention was in a range from about 10⁻¹¹ A to about 10⁻¹⁰ A. That is, because of the nodular defects formed at the interface between the copper material and the barrier material in the copper lines filled by electrochemical plating, the leakage current of the copper lines filled by electrochemical plating is much higher than the leakage current of the copper lines filled according to the exemplary aspects of the present invention (e.g., PVD reflow process).

Thus, the exemplary aspects of the present invention may fabricate narrow copper lines and/or vias which are substantially devoid of sulfur and chlorine (e.g., include less than 1ppm of sulfur and chlorine, respectively) which are the root causes of nodular defect formation. This may allow the exemplary aspects of the present invention to achieve good line-to-line leakage performance (including TDDB performance).

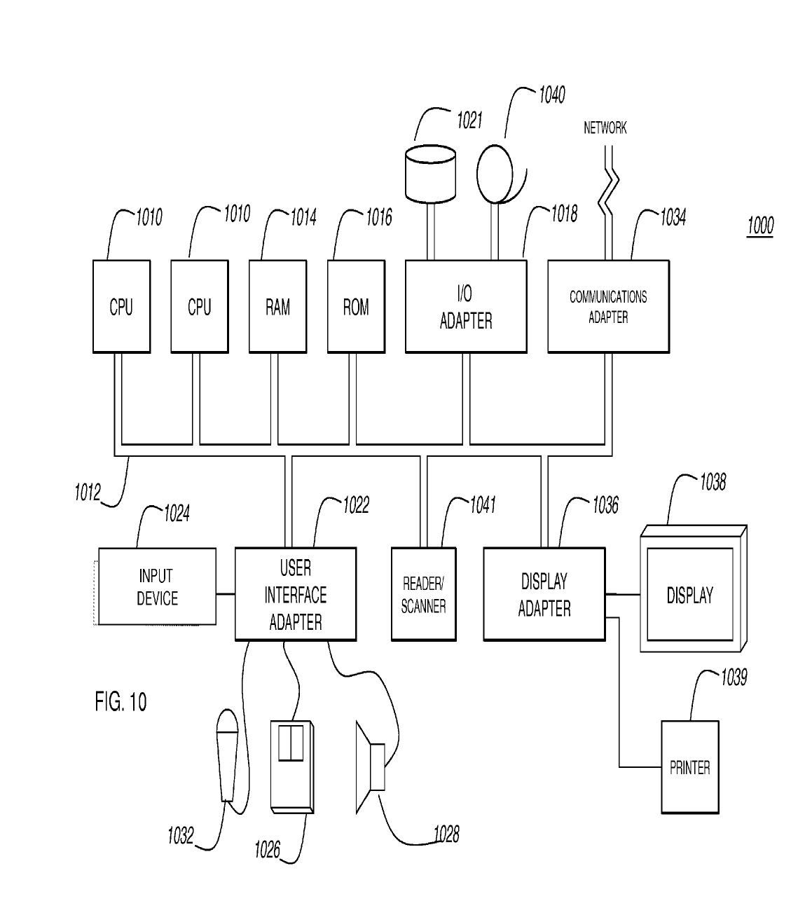

FIG. 10 illustrates a system 1000 including a typical hardware configuration which may be used for implementing a system (e.g., system 400) for forming a semiconductor device, and method (e.g., method 100, 300, 500) of forming a semiconductor device, according to an exemplary aspect of the present invention.

The configuration of the system 1000 has preferably at least one processor or central processing unit (CPU) 1010. The CPUs 1010 are interconnected via a system bus 1012 to a random access memory (RAM) 1014, read-only memory (ROM) 1016, input/output (I/O) adapter 1018 (for connecting peripheral devices such as disk units 1021 and tape drives 1040 to the bus 1012), user interface adapter 1022 (for connecting a keyboard 1024, mouse 1026, speaker 1028, microphone 1032 and/or other user interface device to the bus 1012), a communication adapter 1034 for connecting an information handling system to a data processing network, the Internet, an Intranet, a personal area network (PAN), etc., and a display adapter 1036 for connecting the bus 1012 to a display device 1038 and/or printer 1039. Further, an automated reader/scanner 1041 may be included. Such readers/scanners are commercially available from many sources.

In addition to the system described above, a different aspect of the invention includes a computer-implemented method for performing the above method. As an example, this method may be implemented in the particular environment discussed above.

Such a method may be implemented, for example, by operating a computer, as embodied by a digital data processing apparatus, to execute a sequence of machine-readable instructions. These instructions may reside in various types of signal-bearing media.

Thus, this aspect of the present invention is directed to a programmed product, including non-transitory, signal-bearing media tangibly embodying a program of machine-readable instructions executable by a digital data processor to perform the above method.

Such a method may be implemented, for example, by operating the CPU 1010 to execute a sequence of machine-readable instructions. These instructions may reside in various types of non-transitory, signal bearing media.

Thus, this aspect of the present invention is directed to a programmed product, including non-transistory, signal-bearing media tangibly embodying a program of machine-readable instructions executable by a digital data processor incorporating the CPU 1011 and hardware above, to perform the method of the invention.

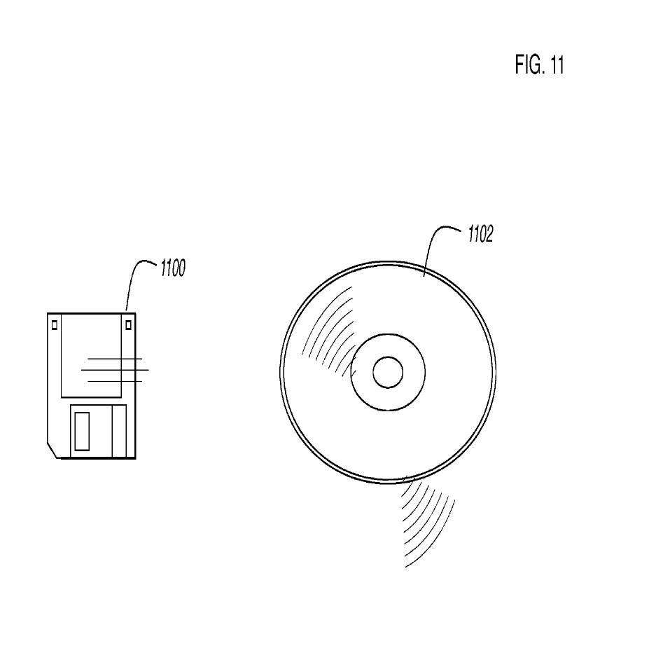

This non-transitory, signal-bearing media may include, for example, a RAM contained within the CPU 1010, as represented by the fast-access storage for example. Alternatively, the instructions may be contained in another non-transitory, signal-bearing media, such as a magnetic data storage diskette 1100 or compact disc 1102 (FIG. 11), directly or indirectly accessible by the CPU 1010.

Whether contained in the computer server/CPU 1010, or elsewhere, the instructions may be stored on a variety of machine-readable data storage media, such as DASD storage (e.g., a conventional “hard drive” or a RAID array), magnetic tape, electronic read-only memory (e.g., ROM, EPROM, or EEPROM), an optical storage device (e.g., CD-ROM, WORM, DVD, digital optical tape, etc.), paper “punch” cards, or other suitable signal-bearing media including transmission media such as digital and analog and communication links and wireless. In an illustrative embodiment of the invention, the machine-readable instructions may comprise software object code, compiled from a language such as C, C++, etc.

Thus, an exemplary aspect of the present invention is directed to a programmable storage medium tangibly embodying a program of machine-readable instructions executable by a digital processing apparatus to perform a method of forming a semiconductor device (e.g., method 100, 300, 500).

With its unique and novel features, the present invention may provide a method of forming a semiconductor device which may have a reduced line-to-line leakage current over conventional methods.

While the invention has been described in terms of one or more exemplary embodiments, those skilled in the art will recognize that the invention can be practiced with modification within the spirit and scope of the appended claims. Specifically, one of ordinary skill in the art will understand that the drawings herein are meant to be illustrative, and the design of the inventive method and system is not limited to that disclosed herein but may be modified within the spirit and scope of the present invention.

Further, Applicant's intent is to encompass the equivalents of all claim elements, and no amendment to any claim the present application should be construed as a disclaimer of any interest in or right to an equivalent of any element or feature of the amended claim.

What is claimed is:

1. A method of forming a semiconductor device, comprising;
depositing first copper material by physical vapor deposition (PVD) on an insulating layer and on a barrier material formed on a sidewall and a bottom of a trench in the insulating layer;
heating the first copper material to reflow the first copper material into the trench;
depositing a second copper material by PVD on the insulating layer, on the barrier material and on the first copper material; and
heating the second copper material to reflow the second copper material into the trench such that the second copper material is formed on the first copper material and on the sidewall of the trench, the first and second copper materials forming a copper layer in the trench, an amount of sulfur and chlorine in the copper layer being less than 1ppm.

2. The method of claim 1, further comprising:
performing chemical mechanical polishing (CMP) to planarize an upper surface of the copper layer and an upper surface of the insulating layer.

3. The method of claim 1, wherein after the heating of the second copper material, an elevation of an upper surface of the second copper material is less than an elevation of the upper surface of the insulating layer.

4. The method of claim 1, further comprising:
repeating the depositing of the second copper material and the heating of the second copper material until an elevation of an upper surface of the second copper material after the heating of the second copper material is greater than an elevation of the upper surface of the insulating layer.

5. The method of claim 1, further comprising:
selecting an optimum deposition rate for the depositing of the first copper material and the second copper material,
wherein the repeating of the depositing of the second copper material and the heating of the second copper material is performed a number of times which is based on the selected deposition rate.

6. The method of claim 1, further comprising:
selecting an optimum number of times for performing the repeating of the depositing of the second copper material and the heating of the second copper material,
wherein the depositing of the first copper material and the second copper material, is based on the selected number of times.

7. The method of claim 2, wherein after the performing of the CMP, an interface between the copper layer and the barrier material is devoid of a nodular defect formation.

8. The method of claim 1, wherein the copper layer comprises one of an interconnect, a narrow line and a via.

9. The method of claim 1, wherein the trench comprises a plurality of elongated trenches, a distance between the plurality of elongated trenches being less than 50nm.

10. The method of claim 1, wherein a width of the trench is less than 40nm.

11. The method of claim 1, wherein the barrier material is selected from a group consisting of Ta, TaN, TaN/Ta, Ti, TiN/Ti, TaN/Ru, TaN/Ta/Ru, TaN/Co, and TaN/Ta/Co.

12. The method of claim 1, wherein the first and second copper materials comprise one of copper and a copper alloy.

13. The method of claim 1, wherein the depositing of the first copper material and the depositing of the second copper material are performed in a deposition chamber, and the heating the first copper material and the heating of the second copper material are performed in a gas chamber which is different from the deposition chamber.

14. The method of claim 1, wherein the depositing of the first copper material, the depositing of the second copper material, the heating the first copper material and the heating of the second copper material are performed in the same chamber.

15. A method of forming a semiconductor device, comprising:
depositing a copper material by physical vapor deposition (PVD) on an insulating layer including a trench, and on a barrier material formed on a sidewall and a bottom of the trench; and
during the depositing of the copper material, heating the copper material and applying an AC bias to the substrate to reflow the copper material into the trench, the copper material forming a copper layer in the trench, an amount of sulfur and chlorine in the copper layer being less than 1 ppm.

16. The method of claim 15, wherein the trench is formed in an upper surface of the insulating layer, and the depositing of the copper material and the heating of the copper material are performed until an elevation of an upper surface of the copper material is greater than an elevation of the upper surface of the insulating layer.

17. The method of claim 15, further comprising:
selecting an optimum deposition rate for the depositing the copper material,
wherein the depositing of the copper material and the heating of the copper material are performed for a duration which is based on the selected optimum deposition rate.

18. The method of claim 15, further comprising:
selecting an optimum duration for performing the depositing of the copper material and the heating of the copper material,
wherein a deposition rate for the depositing of the copper material is based on the selected optimum duration.

19. A semiconductor device, comprising;
an insulating layer including a trench formed in a surface of the insulating layer;
a barrier layer formed on a sidewall and a bottom of the trench; and
a copper layer formed in the trench on the barrier layer and including an upper surface which is coplanar with the surface of the insulating layer, an amount of sulfur and chlorine in the copper layer being less than 1ppm.

20. The semiconductor device of claim 19, wherein the copper layer comprises:
a first copper layer formed in the trench and on the barrier layer; and
a second copper layer formed in the trench and on the first copper layer, the upper surface of the copper layer comprising an upper surface of the second copper layer.
